(19) United States
(12) Patent Application Publication
(10) Pub. No.: US 2025/0167005 A1
(43) Pub. Date: May 22, 2025

(54) METHOD FOR MANUFACTURING A SUBSTRATE WAFER FOR BUILDING GROUP III-V DEVICES THEREON AND A SUBSTRATE WAFER FOR BUILDING GROUP III-V DEVICES THEREON

(71) Applicant: SILTRONIC AG, Munich (DE)

(72) Inventors: Brian MURPHY, Pfarrkirchen (DE); Sarad Bahadur THAPA, Burghausen (DE)

(21) Appl. No.: 18/841,402

(22) PCT Filed: Feb. 15, 2023
(86) PCT No.: PCT/EP2023/053694

§ 371 Date: Aug. 26, 2024

(30) Foreign Application Priority Data
Mar. 3, 2022 (EP) 22159979. 8

(51) Int. Cl. H01L 21/322; H01L 21/02; H01L 21/265

(52) U.S. Cl. CPC H01L 21/3223; H01L 21/02247; H01L 21/02458; H01L 21/0254; H01L 21/26506

(57) ABSTRACT

A substrate wafer for building group III-V devices thereon is manufactured by a method that includes: providing a silicon single crystal wafer; forming a gettering region below a top surface of the silicon single crystal wafer; and forming a nitrogen enriched passivation layer representing a top portion of the substrate wafer.

### CROSS REFERENCE TO RELATED APPLICATIONS

This application is a U.S. National Phase application under 35 U.S.C. § 371 of International Application No. PCT/EP2023/053694, filed on Feb. 15, 2023, and claims benefit to European Patent Application No. 22159979.8, filed on Mar. 3, 2022. The International Application was published in English on Sep. 7, 2023 as WO 2023/165808 A1 under PCT Article 21(2).

### FIELD

The present disclosure provides a method for manufacturing a substrate wafer for building group III-V devices thereon, and a substrate wafer for building group III-V devices thereon.

### BACKGROUND

Group III-V devices, like high-electron-mobility transistors (HEMTs), are known for their superior performance in high power applications and high frequency applications. A vast amount of patent and non-patent literature dealing with this topic is available.

For example, US 2016 0 240 646 A1 discloses the structure and the fabrication of a couple of HEMT devices that may be built over a substrate wafer.

According to US 2014 0 117 502 A1, a gettering region may be provided in a semiconductor substrate wafer.

Many approaches have been pursued to mitigate leakage currents within the device structure and the provision of a passivating layer is one tool to deal with this problem.

For example, WO 2015 123 534 A1 discloses the provision of a buried implantation layer in a buffer region of the group III-V device in order to suppress a leakage current in the direction normal to the substrate.

The inventor of the present disclosure has found that the substrate wafer needs to be improved, in particular in order to prevent dangling bonds from raising defect state densities and charge densities disturbing the proper function of the group III-V device.

### SUMMARY

In an embodiment, the present disclosure provides a substrate wafer for building group III-V devices thereon that is manufactured by a method that includes: providing a silicon single crystal wafer; forming a gettering region below a top surface of the silicon single crystal wafer; and forming a nitrogen enriched passivation layer representing a top portion of the substrate wafer.

### BRIEF DESCRIPTION OF THE DRAWING

Subject matter of the present disclosure will be described in even greater detail below based on the exemplary figure. All features described and/or illustrated herein can be used alone or combined in different combinations. The features and advantages of various embodiments will become apparent by reading the following detailed description with reference to the attached drawing, which illustrate the following:

FIG. 1 displays a sectional view of a substrate wafer according to an aspect of the present disclosure.

### DETAILED DESCRIPTION

The present disclosure is directed to a method for manufacturing a substrate wafer for building group III-V devices thereon, comprising:
providing a silicon single crystal wafer;
forming a gettering region below a top surface of the silicon single crystal wafer; and
forming a nitrogen enriched passivation layer representing a top portion of the substrate wafer.

Dangling bonds are saturated or neutralized by providing at least one nitrogen enriched region that forms a nitrogen enriched passivation layer. The nitrogen enriched passivation layer does not form a separate silicon nitride layer deposited on the silicon single crystal wafer and lacks negative side effects of a separate layer. Moreover, impurities are trapped with a gettering region provided below the top surface of the silicon single crystal wafer.

The nitrogen enriched passivation layer may be formed by diffusing nitrogen or implanting nitrogen ions in a top region of the silicon single crystal wafer. The silicon single crystal wafer may be subjected to an annealing step in a nitrogen containing gas atmosphere in order to diffuse nitrogen into the top region of the silicon single crystal wafer. The annealing step may be performed as a flash lamp anneal. The nitrogen containing atmosphere may contain nitrogen or ammonia (NH₃) or a mixture thereof. The annealing temperature may be in a range of not less than 300° C. and not more than 1350° C. Alternatively, nitrogen ions may be implanted into a region under the top surface of the silicon single crystal wafer and, optionally, subjected to a following thermal treatment. The temperature of the following thermal treatment may be in a range of not less 300° C. and not more than 1350° C. A further alternative comprises introducing nitrogen radicals generated in a plasma to the surface of the silicon single crystal wafer. The concentration of nitrogen that is additionally present at the surface of the silicon single crystal wafer is preferably not less than 1.0×10¹¹ atoms/cm², but less than the quantity to form a stoichiometric silicon nitride layer on the surface of the silicon single crystal wafer. The density of silicon atoms with dangling bonds on the surface is thereby reduced to preferably less than 1×10¹¹ atoms/cm², more preferably less than 1×10¹⁰ atoms/cm² and most preferably less than 1×10⁹ atoms/cm².

In addition to or as an alternative, the nitrogen enriched passivation layer may be formed by depositing an AlN (aluminium nitride) nucleation layer contacting the top surface of the silicon single crystal wafer, and temporarily adding additional nitrogen during the deposition. As a result, the nitrogen concentration in the AlN nucleation layer is higher in a top region and a bottom region of the AlN nucleation layer compared to a region between the top region and the bottom region. For this purpose, the partial pressure of the nitrogen containing precursor gas may be temporarily increased during the deposition of the AlN nucleation layer. The deposition of the AlN nucleation layer may be performed as MOCVD (metal organic chemical vapor deposition), molecular ion-beam epitaxy (MBE). As precursor compounds trimethylaluminum and ammonia can be used for MOCVD. Hydrogen or nitrogen is a suitable carrier gas. The growth temperature of the AlN layer is preferably not less than 700° C. and not more than 1250° C. for MOCVD, and not less than 400° C. and not more than 900° C. for MBE. The AlN nucleation layer has a thickness which is preferably not less than 10 nm and preferably not more than 500 nm, more preferably not more than 200 nm. The nitrogen enriched passivation layer in the top region of the AlN nucleation layer is not thicker than 10 nm and most preferably not more than 5 nm.

In order to enrich the AlN nucleation layer with nitrogen, additional nitrogen precursor gas is applied during the deposition of a bottom region and a top region of the AlN nucleation layer. The partial pressure of a nitrogen containing precursor gas may be temporarily increased during the deposition of the AlN nucleation layer. The concentration of nitrogen that is present in the bottom and the top region of the AlN nucleation layer is at least 1% higher than the Al concentration and at most 50% higher than the Al concentration in the region between the top and bottom regions.

Moreover, a gettering region is formed below a top surface of the silicon single crystal wafer. The gettering region may be formed before the nitrogen enriched passivation layer is formed. The gettering region may be formed by implanting hydrogen ions into the silicon single crystal wafer and annealing the silicon single crystal wafer to form a layer of buried voids. The gettering region may be formed after the formation of the nitrogen enriched passivation layer by implanting the hydrogen ions into the substrate wafer from its back side and annealing the substrate wafer.

Alternatively, the gettering region may be formed as an end-of-range damage (EOR) when the nitrogen ions are implanted in the top region of the silicon single crystal wafer to form the nitrogen enriched passivation layer by implanting nitrogen ions into the silicon single crystal wafer.

Furthermore, an aspect of the present disclosure is directed to a substrate wafer for building group III-V devices, comprising:
a silicon single crystal wafer;
a gettering region below the top surface of the silicon single crystal wafer; and
a nitrogen enriched passivation layer.

The nitrogen enriched passivation layer may be part of the AlN nucleation layer contacting the top surface of the silicon single crystal wafer or may form a top portion of the silicon single crystal wafer.

Preferably, a concentration of nitrogen in the AlN nucleation layer is higher in a top region and a bottom region of the AlN nucleation layer compared to a region between the top region and the bottom region of the AlN nucleation layer.

The gettering region may consist of a layer of buried voids or of an end-of-range damage.

The silicon single crystal wafer may be a wafer cut from a silicon single crystal that has been grown according to the CZ-method by pulling a seed crystal from a melt contained in a crucible or FZ-method. The silicon single crystal wafer has a diameter that is at least 150 mm, preferably at least 200 mm and most preferably 300 mm. The lattice orientation of the silicon single crystal wafer may be preferably (100) or (111) or (110).

The description of the present disclosure is continued with referral to a drawing.

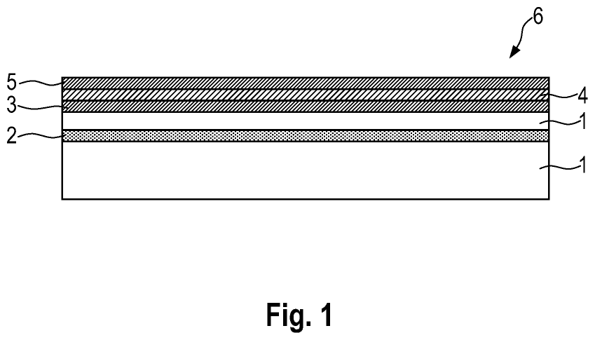

FIG. 1 displays a sectional view of a substrate wafer according to an aspect of the present disclosure.

The substrate wafer 6 displayed in FIG. 1 comprises a silicon single crystal wafer 1, a gettering region 2 and an AlN nucleation layer forming the nitrogen enriched passivation layer and consisting of a bottom region 3, a top region 5 and an intermediate region 4. The nitrogen concentration is higher in a top region 5 and the bottom region 3 compared to the nitrogen concentration in the intermediate region 4.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS EMPLOYED

1 silicon single crystal wafer
2 gettering region
3 bottom region
4 intermediate region
5 top region
6 substrate wafer

1. A method for manufacturing a substrate wafer for building group III-V devices thereon, the method comprising:
providing a silicon single crystal wafer;
forming a gettering region below a top surface of the silicon single crystal wafer; and
forming a nitrogen enriched passivation layer representing a top portion of the substrate wafer.

2. The method as claimed in claim 1, wherein the nitrogen enriched passivation layer is formed by diffusing nitrogen or implanting nitrogen ions in a top region of the silicon single crystal wafer.

3. The method as claimed in claim 2, wherein the nitrogen enriched passivation layer is formed by subjecting the silicon single crystal wafer to a thermal treatment in an atmosphere containing a nitriding gas.

4. The method as claimed in claim 2, wherein the gettering region is formed as an end-of-range damage upon the nitrogen ions being implanted in the top region of the silicon single crystal wafer.

5. The method as claimed in claim 1, wherein the gettering region is formed by implanting hydrogen ions into the silicon single crystal wafer and annealing the silicon single crystal wafer to form a layer of buried voids below the top surface of the silicon single crystal wafer.

6. The method as claimed in claim 1, wherein the nitrogen enriched passivation layer is formed by depositing an aluminium nitride (AlN) nucleation layer contacting the top surface of the silicon single crystal wafer, the nitrogen concentration in the AlN nucleation layer being higher in a top region and a bottom region of the AlN nucleation layer compared to an intermediate region between the top region and the bottom region.

7. The method as claimed in claim 5, the method further comprising:
temporarily increasing a partial pressure of a nitrogen containing precursor gas during the deposition of the AlN nucleation layer.

8. A substrate wafer for building group III-V devices, the substrate wafer comprising:
a silicon single crystal wafer;
a gettering region below the top surface of the silicon single crystal wafer; and
a nitrogen enriched passivation layer.

9. The substrate wafer as claimed in claim 8, wherein the nitrogen enriched passivation layer forms a top portion of the substrate wafer.

10. The substrate wafer as claimed in claim 8, wherein the nitrogen enriched passivation layer is part of an aluminium nitride (AlN) nucleation layer contacting a top surface of the silicon single crystal wafer.

11. The substrate wafer as claimed in claim 10, wherein a concentration of nitrogen in the AlN nucleation layer is higher in a top region and a bottom region of the AlN nucleation layer as compared to a region between the top region and the bottom region.

12. The substrate wafer as claimed in claim 8, wherein the gettering region consists of a layer of buried voids.

13. The substrate wafer as claimed in claim 8, wherein the gettering region consists of an end-of-range damage.
